(19) United States
(12) Patent Application Publication
(10) Pub. No.: US 2003/0230756 A1
(43) Pub. Date: Dec. 18, 2003

(54) Technique for packaging an optical module

(76) Inventor: Ian C. Prees, Chelmsford, MA (US)

Correspondence Address: Thomas E. Anderson, Hunton & Williams, 1900 K Street, N.W., Washington, DC, 20006-1109, US

(21) Appl. No.: 10/390,154

(22) Filed: Mar. 18, 2003

Related U.S. Application Data
(60) Provisional application No. 60/364,636, filed on Mar. 18, 2002.

(51) Int. Cl. H01L 33/00

(52) U.S. Cl. 257/98; 257/99; 257/81

(57) ABSTRACT

A technique for packaging an optical module is disclosed. In one particular exemplary embodiment, the technique may be realized as an optical module packaging apparatus comprising an optical module having a first slip-fit engagement means, at least one support rail for supporting the optical module, and an end cap attached to the at least one support rail. The optical module packaging apparatus may also comprise an enclosure for enclosing the optical module and the at least one support rail and engaging the end cap, wherein the enclosure has a second slip-fit engagement means for engaging the first slip-fit engagement means.

### CROSS-REFERENCE TO RELATED APPLICATIONS

This patent application claims priority to U.S. Provisional Patent Application No. 60/364,636, filed Mar. 18, 2002, which is hereby incorporated by reference herein in its entirety.

### FIELD OF THE INVENTION

The present invention relates generally to optical module packaging techniques and, more particularly, to a technique for packaging an optical module so as to minimize the effects of bending moments and torsional stresses, as well as the effects of temperature gradients.

### BACKGROUND OF THE INVENTION

The traditional method for packaging an optical module is to mount all optical elements within a monolithic steel block or tube. This tube is then mounted very carefully with flexible brackets so as to minimize any bending moment that may be transmitted to the optical elements during the mounting process. Such bending stresses can impair the performance of the optical module significantly. Another weakness is non-uniform heating of the optical elements due to inconsistent thermal conduction paths. Non-uniform heating can cause deformations in an optical path, thereby impairing the performance of the optical module.

In view of the foregoing, it would be desirable to provide a technique for packaging an optical module which overcomes the above-described inadequacies and shortcomings. More particularly, it would be desirable to provide a technique for packaging an optical module so as to minimize the effects of bending moments and torsional stresses, as well as the effects of temperature gradients, in an efficient and cost effective manner.

### SUMMARY OF THE INVENTION

According to the present invention, a technique for packaging an optical module is provided. In one particular exemplary embodiment, the technique may be realized as an optical module packaging apparatus. Such an optical module packaging apparatus may comprise an optical module having a first slip-fit engagement means, at least one support rail for supporting the optical module, and an end cap attached to the at least one support rail. The optical module packaging apparatus may also comprise an enclosure for enclosing the optical module and the at least one support rail and engaging the end cap, wherein the enclosure has a second slip-fit engagement means for engaging the first slip-fit engagement means.

In accordance with other aspects of this particular exemplary embodiment of the present invention, the optical module may beneficially be a dense wavelength division multiplexing optical module containing a plurality of optical elements. Also, the optical module may beneficially be rectangular in shape.

In accordance with further aspects of this particular exemplary embodiment of the present invention, the first slip-fit engagement means may beneficially be a cavity formed in the optical module. Also, the second slip-fit engagement means may beneficially be a pin formed within the enclosure. Further, the second slip-fit engagement means may beneficially be formed as a part of the enclosure. Alternatively, the second slip-fit engagement means may beneficially be formed separate from the enclosure and secured to the enclosure by welding, an adhesive, and/or a snap-fit arrangement. Additionally, the engagement between the first slip-fit engagement means and the second slip-fit engagement means may beneficially form the only point of contact between the optical module and the enclosure.

In accordance with additional aspects of this particular exemplary embodiment of the present invention, the at least one support rail may beneficially have a thin cross-sectional area for minimizing thermal conduction to the optical module. Also, the at least one support rail may beneficially be formed of a rigid material for withstanding mechanical stresses. Further, the at least one support rail may beneficially be formed of a metallic, ceramic, plastic, and/or composite material. Additionally, the at least one support rail may beneficially comprise two support rails for supporting two sides of the optical module.

In accordance with still other aspects of this particular exemplary embodiment of the present invention, the end cap may beneficially comprise portal means for allowing at least one optical fiber to pass therethrough for connection to the optical module. Also, the end cap may beneficially be formed of a metallic, ceramic, plastic, and/or composite material. Further, the end cap may beneficially be secured to the enclosure by welding, an adhesive, and/or a snap-fit arrangement.

In accordance with still further aspects of this particular exemplary embodiment of the present invention, the enclosure may beneficially be formed of a rigid material for withstanding mechanical stresses. Accordingly, the enclosure may beneficially be formed of a metallic, ceramic, plastic, and/or composite material. Further, the enclosure may beneficially be rectangular in shape.

The present invention will now be described in more detail with reference to exemplary embodiments thereof as shown in the appended drawings. While the present invention is described below with reference to preferred embodiments, it should be understood that the present invention is not limited thereto. Those of ordinary skill in the art having access to the teachings herein will recognize additional implementations, modifications, and embodiments, as well as other fields of use, which are within the scope of the present invention as disclosed and claimed herein, and with respect to which the present invention could be of significant utility.

### BRIEF DESCRIPTION OF THE DRAWINGS

In order to facilitate a fuller understanding of the present invention, reference is now made to the appended drawings. These drawings should not be construed as limiting the present invention, but are intended to be exemplary only.

FIG. 1 shows a perspective view of an optical module packaging apparatus in accordance with the present invention.

FIG. 2 shows a partial cross-sectional side view of an optical module packaging apparatus in accordance with the present invention.

### DETAILED DESCRIPTION OF EXEMPLARY EMBODIMENT(S)

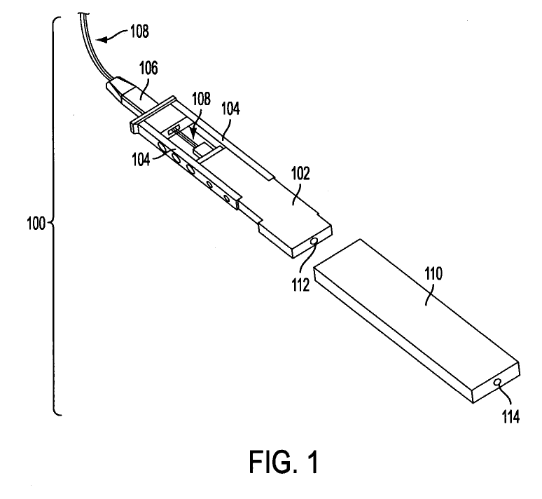

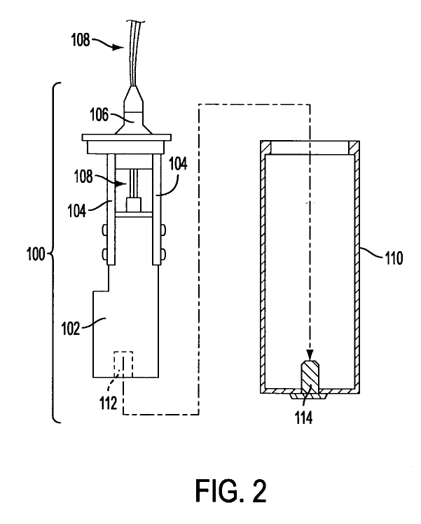

Referring to FIGS. 1 and 2, there are shown a perspective view and partial cross-sectional side view, respectively, of an optical module packaging apparatus 100 in accordance with the present invention. The optical module packaging apparatus 100 comprises an optical module 102 supported by a pair of support rails 104. The support rails 104 are attached to an end cap 106. The end cap 106 preferably maintains internal portal means for allowing a plurality of optical fibers 108 to pass therethrough. The plurality of optical fibers 108 are connected to the optical module 102 for providing optical signals to and from the optical module 102. The optical module 102 comprises optical elements (not shown) for processing the optical signals provided by the plurality of optical fibers 108.

The optical module packaging apparatus 100 further comprises an enclosure 110 for enclosing the optical module 102 and the support rails 104 and a first portion of the end cap 106. The enclosure 110 engages a second portion of the end cap 106 such that the enclosure 110 is secured to the end cap 106. For example, the enclosure 110 may secured to the end cap 106 by welding, an adhesive, or a snap-fit arrangement.

The optical module 102 comprises a first slip-fit engagement means 112 formed at one end thereof. The enclosure 110 comprises a second slip-fit engagement means 114 formed internally at one end thereof. The first slip-fit engagement means 112 mates with the second slip-fit engagement means 114 when the optical module 102 is inserted into the enclosure 110. Thus, the optical module 102 is supported within the enclosure 110 by the support rails 104 and the mating arrangement between the first slip-fit engagement means 112 and the second slip-fit engagement means 114. This packaging arrangement for the optical module 102 minimizes the effects of external bending moments and torsional stresses, as well as the effects of external temperature gradients, as described in more detail below.

The optical module 102 may be, for example, a Dense Wavelength Division Multiplexer (DWDM) module, and thus would contain all of the optical elements needed for performing the functions of a DWDM module. These optical elements are typically mounted within or on a surface of the optical module 102, which may be formed of metal, ceramic, plastic, and/or composite materials.

As shown in FIGS. 1 and 2, the first slip-fit engagement means 112 may be a cavity formed in the optical module 102. However, the present invention is not limited in this regard. For example, the first slip-fit engagement means 112 may be a pin for engaging a cavity formed in the enclosure 110.

As also shown in FIGS. 1 and 2, the optical module 102 is supported by a pair of support rails 104, which are in turn attached to the end cap 106. Although two support rails 104 are shown in FIGS. 1 and 2, the present invention is not limited in this regard. For example, a single support rail or multiple support rails may support the optical module 102. Further these single or multiple support rails 104 may support the optical module 102 and attach to the end cap 106 in a variety ways. For example, the optical module 102 may have features (e.g., screw holes, mating knobs, adhesives, etc.) formed therein for attaching to the single or multiple support rails 104. Also, single or multiple support rails 104 may be formed as part of the end cap 106 or have features (e.g., screw holes, mating knobs, adhesives, etc.) formed therein for attaching to the end cap 106. In any case, the single or multiple support rails 104 preferably have a thin cross-sectional area so as to minimize the conduction of heat to the optical module 102, but also have a geometry that is robust enough to withstand shock and vibration requirements. The single or multiple support rails 104 may be formed of metal, ceramic, plastic, and/or composite materials.

As mentioned above, the end cap 106 preferably maintains internal portal means for allowing a plurality of optical fibers 108 to pass therethrough, and it may be secured to the enclosure 110 by welding, an adhesive, or a snap-fit arrangement. Thus, the end cap 106 may be formed of metal, ceramic, plastic, and/or composite materials.

As shown in FIGS. 1 and 2, the enclosure 110 may be rectangular in shape for accommodating the optical module 102, which may also be rectangular in shape for accommodating truncated optical elements. Such a rectangular shape is more beneficial in terms of packaging and mounting than tubular shaped optical modules, as discussed above.

As also shown in FIGS. 1 and 2, the second slip-fit engagement means 114 may be a pin formed internally at one end of the enclosure 110. However, the present invention is not limited in this regard. For example, the second slip-fit engagement means 114 may be a cavity for engaging a pin formed on the optical module 102. Also, the second slip-fit engagement means 114 may be formed as a part of the enclosure 110 or may be otherwise secured to the enclosure 110. For example, as shown more clearly in FIG. 2, the second slip-fit engagement means 114 may be a pin that that may be secured to the enclosure 110 by welding, an adhesive, or a snap-fit arrangement. Further, the second slip-fit engagement means 114 may be separately formed (as shown in FIG. 2) or formed as part of an end cap for the enclosure 110. Such an end cap may be secured to the enclosure 110 by welding, an adhesive, or a snap-fit arrangement.

As mentioned above, the enclosure 110 may be secured to the end cap 106 by welding, an adhesive, or a snap-fit arrangement. Thus, the enclosure 110 may be formed of metal, ceramic, plastic, and/or composite materials.

The above-described optical module packaging apparatus 100, wherein the optical module 102 is fixed at a first end and engaged through slip-fit engagement means at a second end, allows for a minimum stress condition to exist even with differing thermal expansion rates for materials of the apparatus 100 or large thermal transients between internal and external components of the apparatus 100. Also, with the optical module 102 fixed at a first end and slip-fit engaged at a second end, stresses induced in the mounting of the enclosure 110 are not allowed to be transferred to the optical module 102. Other benefits of the apparatus 100 include additional shock isolation provided by the support rails 104, and shock/vibe absorption relative to the enclosure 110. The optical module 102 is completely constrained relative to the enclosure 110 by the support rails 104 and the end cap 106. Also, the optical module 102 is supported by slip-fit engagement means with the enclosure 110. This arrangement allows the optical module 102 to expand and contract at different rates than the enclosure 110 as temperature changes. This arrangement also allows the optical module 102 to be isolated from any bending or torsional stress the enclosure 110 may see (e.g., during mounting).

In summary, the present invention comprises an opto-mechanical configuration that decouples exterior thermal and mechanical stress from an internal optical structure by means of: 1.) an optical module mounting arrangement that minimizes external bending moments and torsional stresses, and provides a long thermal path; 2.) slip-fit engagement means that allows for the compensation of thermal expansion and rotational stress; and 3.) a sliding-fit assembly arrangement.

The present invention is not to be limited in scope by the specific embodiments described herein. Indeed, various modifications of the present invention, in addition to those described herein, will be apparent to those of ordinary skill in the art from the foregoing description and accompanying drawings. Further, although the present invention has been described herein in the context of a particular implementation in a particular environment for a particular purpose, those of ordinary skill in the art will recognize that its usefulness is not limited thereto and that the present invention can be beneficially implemented in any number of environments for any number of purposes.

1. An optical module packaging apparatus comprising:
an optical module having a first slip-fit engagement means;
at least one support rail for supporting the optical module;
an end cap attached to the at least one support rail; and
an enclosure for enclosing the optical module and the at least one support rail and engaging the end cap, the enclosure having a second slip-fit engagement means for engaging the first slip-fit engagement means.

2. The apparatus as defined in claim 1, wherein the optical module is a dense wavelength division multiplexing optical module containing a plurality of optical elements.

3. The apparatus as defined in claim 1, wherein the first slip-fit engagement means is a cavity formed in the optical module.

4. The apparatus as defined in claim 1, wherein the at least one support rail has a thin cross-sectional area for minimizing thermal conduction to the optical module.

5. The apparatus as defined in claim 4, wherein the at least one support rail is formed of a rigid material for withstanding mechanical stresses.

6. The apparatus as defined in claim 5, wherein the at least one support rail is formed of one or more of a metallic, ceramic, plastic, and composite material.

7. The apparatus as defined in claim 6, wherein the at least one support rail comprises two support rails for supporting two sides of the optical module.

8. The apparatus as defined in claim 1, wherein the end cap comprises portal means for allowing at least one optical fiber to pass therethrough for connection to the optical module.

9. The apparatus as defined in claim 8, wherein the end cap is formed of one or more of a metallic, ceramic, plastic, and composite material.

10. The apparatus as defined in claim 1, wherein the second slip-fit engagement means is a pin formed within the enclosure.

11. The apparatus as defined in claim 1, wherein the second slip-fit engagement means is formed as a part of the enclosure.

12. The apparatus as defined in claim 1, wherein the second slip-fit engagement means is formed separate from the enclosure and secured to the enclosure by one or more of welding, an adhesive, and a snap-fit arrangement.

13. The apparatus as defined in claim 1, wherein the enclosure is secured to the end cap by one or more of welding, an adhesive, and a snap-fit arrangement.

14. The apparatus as defined in claim 1, wherein the engagement between the first slip-fit engagement means and the second slip-fit engagement means forms the only point of contact between the optical module and the enclosure.

15. The apparatus as defined in claim 1, wherein the enclosure is formed of a rigid material for withstanding mechanical stresses.

16. The apparatus as defined in claim 15, wherein the enclosure is formed of one or more of a metallic, ceramic, plastic, and composite material.

17. The apparatus as defined in claim 1, wherein the enclosure is rectangular in shape.

18. The apparatus as defined in claim 1, wherein the optical module is rectangular in shape.
